(19) United States
(12) Patent Application Publication
(10) Pub. No.: US 2012/0217583 A1
(43) Pub. Date: Aug. 30, 2012

(54) SEMICONDUCTOR DEVICE AND METHOD FOR FORMING THE SAME

(76) Inventors: Huilong Zhu, New York, NY (US); Zhijiong Luo, New York, NY (US); Haizhou Yin, New York, NY (US); Qingqing Liang, Beijing (CN)

(21) Appl. No.: 13/144,375

(22) PCT Filed: Feb. 24, 2011
(86) PCT No.: PCT/CN11/71253

§ 371 Date: Jul. 13, 2011

(30) Foreign Application Priority Data
Feb. 24, 2011 (CN) 201010529707.3

(51) Int. Cl. H01L 21/336; H01L 29/78

(52) U.S. Cl. 257/368; 438/294; 438/289; 257/E29.02; 257/E29.255; 257/E21.409

(57) ABSTRACT

A semiconductor structure and a method for forming the structure are provided. The semiconductor structure has a STI structure which has a top surface higher than or as high as that of source/drain stressors. A dummy gate and a spacer are added on the STI structure. The method comprises: providing a semiconductor substrate; embedding a STI structure in the semiconductor substrate in order to form isolated active areas; forming a gate stack on the active area, and forming a dummy gate on the STI structure; forming a first spacer on sidewalls of the dummy gate, wherein a part of the first spacer lands on the active area; and embedding source/drain stressors in the semiconductor substrate and at opposite sides of the gate stack, wherein the top surface of the STI structure is higher than or as high as that of the source/drain stressor.

### CROSS REFERENCE TO RELATED APPLICATIONS

The present application is a Section 371 National Stage Application of, and claims priority to, International Application No. PCT/CN2011/071253, filed on Feb. 24, 2011, which claims the priority of Chinese Patent Application No. 201010529707.3, and filed on Oct. 28, 2010. Both the International application and the Chinese application are incorporated herein by reference in their entireties.

### BACKGROUND OF THE INVENTION

1. Field of the Invention

The present invention relates to semiconductor manufacturing technology, and particularly, to a semiconductor structure having a source/drain stressor and a shallow trench isolation (STI) structure and a method for forming the same.

2. Background of the Invention

With continuous development of semiconductor technology, sizes of semiconductor devices are shrinking, in particular, reduction in integrated circuit (IC) pitches facilitates to reduce the manufacturing cost. However, it is a challenge to reduce the sizes, while maintaining or even improving the performances of semiconductor devices at the same time.

For example, referring to FIG. 2, when the pitch between MOSFETs is less than 150 nm, negative interface effects may be generated between a STI structure and a source/drain stressor, which leads to channel stress loss and influences performances of the device. Referring to FIG. 1a, the top surface of a STI structure 10 is higher than that of a source/drain stressor 20, which ensures channel 30 a perfect structure with strong stress. In fact, according to FIG. 1b, the height of STI will be lost due to excessive cleaning, dry or wet etching, and the like in manufacturing processes. When the top surface of the STI structure 10 is lower than that of the source/drain stressor 20, stress is relieved, that is, the stress in channel is reduced.

### SUMMARY OF THE INVENTION

Embodiments of the present invention are intended to resolve at least one of the problems described above, and particularly to reduce the channel stress loss in MOSFET devices due to interface effects between a STI structure and a source/drain stressor. Meanwhile, the semiconductor structure and the method for forming the structure provided according to the present invention are beneficial for improving the quality of source/drain regions.

To achieve the object, according to one embodiment of present invention, it is provided a semiconductor structure, comprising: a semiconductor substrate; a gate stack on the semiconductor substrate; a source/drain stressor on opposite sides of the gate stack and embedded in the semiconductor substrate; a shallow trench isolation (SOI) structure embedded in the semiconductor substrate, the SOI structure having a top surface higher than or as high as a top surface of the source/drain stressor, and dividing the semiconductor substrate to form isolated active areas; and a dummy gate formed on the top surface of the shallow trench isolation structure, wherein a first spacer is formed on sidewalls of the dummy gate, and a part of the first spacer lands on the active area.

Optionally, for pMOSFETs, the source/drain stressors comprises SiGe in which Ge percentage range from 15% to 70%; and for nMOSFETs, the source/drain stressors comprises Si:C in which C percentage range from 0.2% to 2%.

Optionally, a second spacer is formed on the sidewalls of the gate stack.

Firstly, since a part of the first spacer lands on the active area in the semiconductor substrate, the STI structure is fully covered such that the STI structure is protected from being damaged in following processes, such as excessive cleaning, etching, and so on. Secondly, a part of the substrate on a side of the STI structure can be reserved, which can be used as a seeding layer to form source/drain regions in an epitaxial growth process, and thus the quality of the source/drain regions can be improved.

Furthermore, according to one embodiment of the present invention, it is provided a method for forming the described semiconductor structure, comprising: a: providing a semiconductor substrate; b: embedding a shallow trench isolation structure in the semiconductor substrate to form isolated active areas, wherein a top surface of the shallow trench isolation structure is higher than or as high as a top surface of the active area; c: forming a gate stack on the active area, and forming a dummy gate on the STI structure; d: forming a first spacer on sidewalls of the dummy gate, wherein a part of the first spacer lands on the active area; and e: forming source/drain stressors in the semiconductor substrate on opposite sides of the gate stack, wherein the top surface of the shallow trench isolation structure is higher than or as high as a top surface of the source/drain stressors.

Optionally, the step b for forming the shallow trench isolation structure comprises: forming a hard mask layer on the semiconductor substrate; etching the hard mask layer and the semiconductor substrate to form a trench; filling the trench to form an insulating layer; etching back the insulating layer until a top surface of the insulating layer is higher than or as high as the top surface of the active area; and removing the hard mask layer.

Optionally, the step d further comprises forming a second spacer on the sidewalls of the gate stack.

Optionally, before forming the first spacer and the second spacer, performing a tilted-angle ion implantation on the active area of the semiconductor substrate to form halo implant regions and/or to form source/drain extension regions.

Optionally, the step e for forming source/drain stressors comprises: etching the semiconductor substrate by using the first spacer and the second spacer as a mask to form a groove in the semiconductor substrate and on both sides of the gate stack, wherein a part of the semiconductor substrate between the groove and the shallow trench isolation structure is reserved; and forming the source/drain stressor in the groove by an epitaxial growth process with the reserved part of the semiconductor substrate as a seeding layer.

Optionally, forming the source/drain stressor by the epitaxial growth process comprises: for pMOSFETs, epitaxially growing SiGe in which Ge percentage ranges from 15% to 70% in the groove; and for nMOSFETs, epitaxially growing Si:C in which C percentage ranges from 0.2% to 2% in the groove.

According to embodiments of the present invention, a STI structure which has a top surface higher than or as high as that of a source/drain stressor is formed in a MOSFET device, and a dummy gate structure and a spacer are added on the STI structure. The structure formed according to embodiments can effectively prevent the height of the STI structure from being reduced by subsequent processes, such as excessive cleaning, etching, and so on. Thus, the channel stress loss can be reduced or avoided, and the performances of the device can be improved. In addition, a part of the added spacer on the dummy gate stack lands on the active area of the semiconductor substrate, and a part of the substrate on a side of the STI structure is reserved when etching to form a groove for the source/drain region. Therefore, source/drain regions may be formed through epitaxial growth by using the reserved part of the substrate as a seeding layer, and thus the quality of the source/drain regions can be improved.

Some additional aspects and advantages of the present invention will be partly described in detail and will become explicit in the following description, or can be understood in the application of the embodiments of the present invention.

### BRIEF DESCRIPTION OF THE DRAWINGS

The accompanying drawings, which are incorporated herein and form a part of the specification, and, together with the description, further serve to explain the principles of the embodiments of the invention and to enable a person skilled in the art to make and use the invention.

FIG. 1 is a schematic view showing a structural relationship between a STI structure and a source/drain stressor in a MOSFET device in prior art, wherein FIG. 1a and FIG. 1b are schematic structural views respectively in perfect and actual condition;

FIG. 2 is a schematic cross-sectional view of a semiconductor structure according to an embodiment of the present invention; and

FIGS. 3-12 are cross-sectional views of intermediate structures in a method for manufacturing a semiconductor structure according to an embodiment of the present invention.

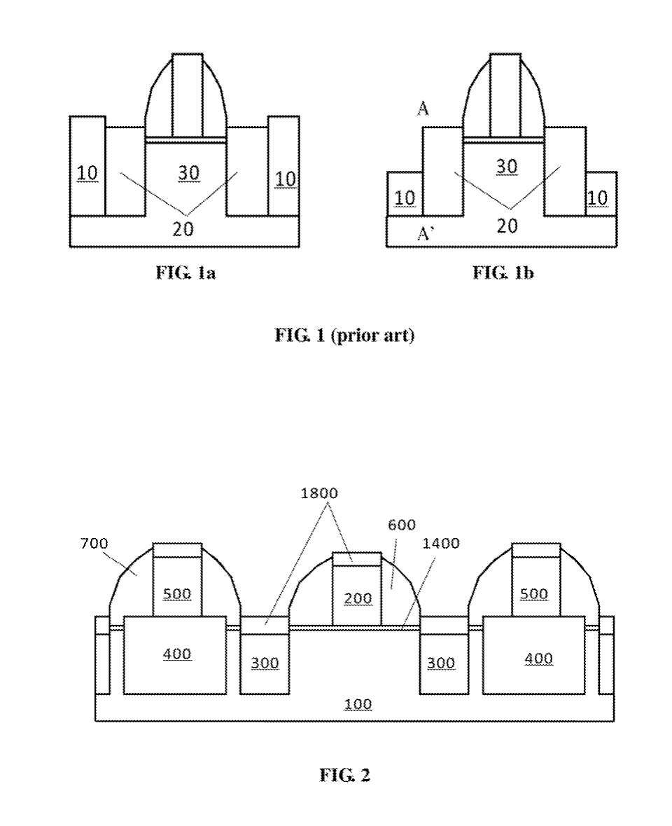

### DETAILED DESCRIPTION OF THE EMBODIMENTS

Hereafter, the present invention will be described in detail with reference to embodiments, in conjunction with the accompanying drawings.

Many different embodiments and examples are provided to manufacture different structures of the present invention as disclosed as below. Components and setup of given embodiments are described only as some examples to simplify the publishing of the present invention in the following part of the application, while not to limit the scope of the present invention. In addition, some mentioned figures and/or marks can be repeated in the different embodiments of the present invention, for simplifying and easily understanding, without indication of relationship in examples and setup of different embodiments that are discussed. Also, it occurs to those skilled in the art that examples of different given techniques and/or materials in the embodiments of the present invention can be applied in other techniques and/or with other materials. In addition, the structure of the first element formed on the second element described below can comprise the embodiments in which the first element and second element contact each other directly, also comprise the embodiments in which other elements are formed between the first and the second elements, thus the first element may not contact the second element.

FIG. 2 is a schematic cross-sectional view of a semiconductor structure according to an embodiment of the present invention. The semiconductor structure comprises: a semiconductor substrate 100, a gate stack 200 on the semiconductor substrate 100; source/drain stressors 300 on both sides of the gate stack 200 and embedded in the semiconductor substrate 100; a STI structure 400 embedded in the semiconductor substrate 100 and having a top surface higher than or as high as that of the source/drain stressor 300; and a dummy gate 500 formed on the top surface of the STI structure 400 and having a first spacer 600 formed on sidewalls of the dummy gate 500. A part of the first spacer 600 lands on an active area 900 of the semiconductor substrate 100, which has the following advantages. Firstly, the STI structure 400 under the dummy gate 500 is fully covered such that the STI structure 400 is protected from being damaged in the following processes, such as excessive cleaning, etching, and so on. Secondly, a part of the substrate on one side of the STI structure can be reserved while being etched to form the source/drain region and can be used as a seeding layer in an epitaxial growth. Thus, the quality of the source/drain region can be improved. In addition, “as high as” in the present invention means that the difference of heights between two planes is in an allowable range according to the manufacturing processes.

Optionally, a second spacer 700 is formed on sidewalls of the gate stack 200. As for pMOSFETs, the source/drain stressor 300 may comprise SiGe in which Ge percentage is in a range from 15% to 70% to generate a compressive stress in the channel. As for nMOSFETs, the source/drain stressor 300 may comprise Si:C in which C percentage is in a range from 0.2% to 2% to generate a tensile stress in the channel. Furthermore, an in-situ doping process may be performed on both SiGe or Si:C to improve the stress effects. A metal silicide layer 1800 is formed on the top surface of the gate stack 200, the dummy gate 500, and the source/drain stressors 300. Optionally, the metal silicide layer 1800 may be NiPtSi.

The semiconductor structure has been described above according to the embodiment of the present invention. It should be noted that those skilled may select different manufacturing processes to manufacture the field effect transistor structure described above, for example, different product lines, different processes, and so on. However, as long as the field effect transistor structures manufactured by these processes are provided with the substantially same structure, and the substantially same effect resulted in, the structures should be comprised in the scope of the present invention. For making the present invention understood more clearly, the method and art for forming the field effect transistor in the present invention will be described in detail as below. The following steps are schematic, and are not a limitation to the present invention, so those skilled in the art can also perform it in other ways. The following embodiments can effectively reduce the manufacturing cost.

A method for forming the semiconductor structure according to an embodiment of the present invention comprises the following steps.

Step a: a semiconductor substrate 100 is provided. In one embodiment, the semiconductor substrate 100 is made of bulk silicon. In other embodiments, the semiconductor substrate may comprise any suitable semiconductor substrate material, which may be, but not limited to, silicon, germanium, SiGe, silicon on insulator (SOI), silicon carbide, gallium arsenide, or any III-V group compound semiconductor, and so on. The semiconductor substrate 100 may be doped of all types, in accordance with the well-known design demands (e.g. for a p-type substrate or an n-type substrate). In addition, the substrate 100 may optionally comprise an epitaxial layer, which may be changed by stress for performance enhancement.

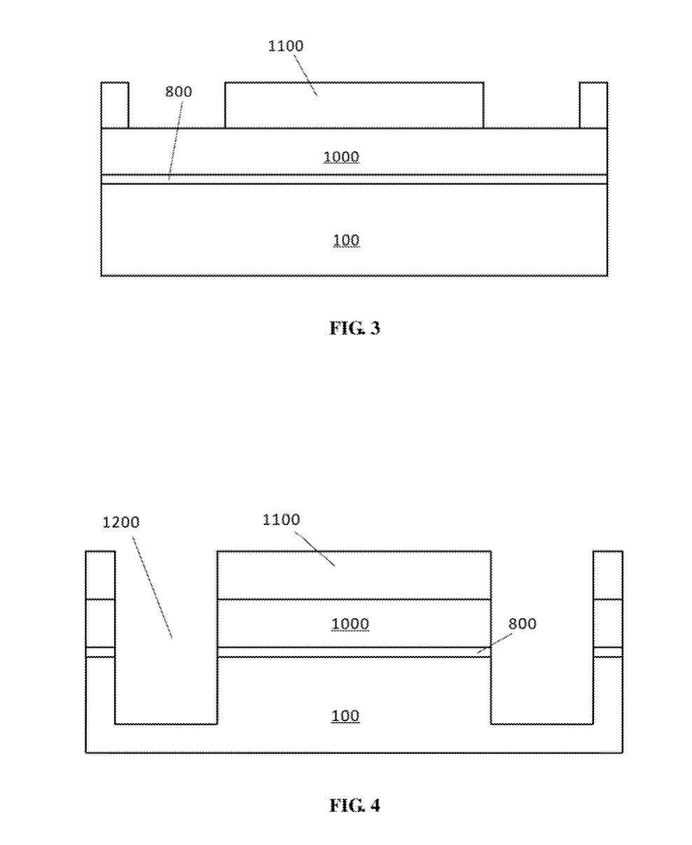

Step b: a STI structure 400 is embedded in the semiconductor substrate 100, in order to form isolated active areas 900, wherein a top surface of the STI structure 400 is higher than or as high as those of the active areas 900. Specifically, as shown in FIG. 3, firstly, an oxide liner 800 (e.g. silicon oxide) having a thickness ranged from 10 nm to 20 nm is formed on the semiconductor substrate 100. Secondly, a hard mask layer 1000 (e.g. silicon nitride) having a thickness ranged from 30 nm to 150 nm is formed on the oxide liner 800. Then a patterned photoresist 1100 is formed on the hard mask layer 1000 by using a mask with the preset STI pattern. It should be noted that, in embodiments of the present invention, the methods for forming the dielectric layer (e.g. the oxide liner 800, the hard mask layer 1000, a high-k dielectric layer 1400, a first spacer 600, and a second spacer 700, and so on), if there is no particular illustration, may be general deposition processes, such as sputtering, pulsed laser deposition (PLD), metal-organic chemical vapor deposition (MOCVD), atomic layer deposition (ALD), plasma enhanced atomic layer deposition (PEALD), plasma enhanced chemical vapor deposition(PECVD), and other suitable processes.

Referring to FIG. 4, the patterned photoresist 1100 is used as a mask to etch the hard mask layer 1000, the oxide liner 800 and the semiconductor substrate 100 sequentially in order to form a trench 1200. The etching process may be performed by using a reactive ion etching (RIE). The depth of the etching process may be between 100 nm and 500 nm.

Referring to FIG. 5, the patterned photoresist 1100 is removed and an insulating layer 1300 is formed in the trench 1200. For example, the insulating layer 1300 may be formed by the following steps: an oxide (e.g. silicon oxide) is deposited and planarized by using the hard mask layer 1000 as a stopper layer. In an embodiment, the planarization process is performed by using the chemical mechanical polishing (CMP) process.

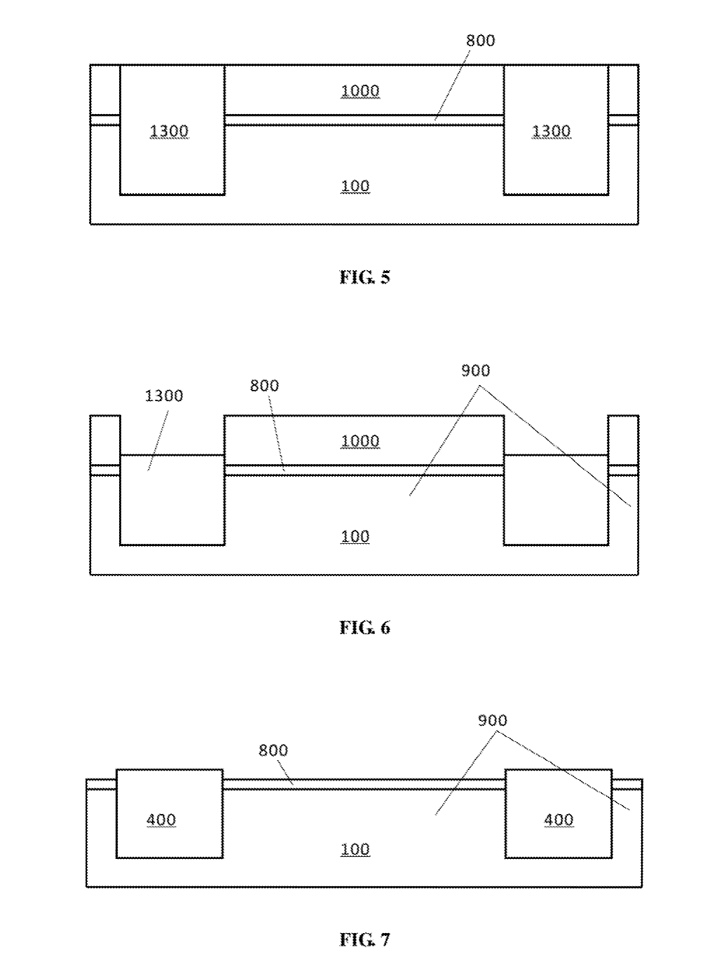

Referring to FIG. 6, the insulating layer 1300 is etched back to make the surface of the insulating layer 1300 higher than or as high as that of the active area 900.

Finally, the hard mask layer 1000 (silicon nitride) is removed to form STI structures 400, in order that the isolated active areas 900 are formed on the semiconductor substrate 100. The top surface of the STI structure 400 is higher than or as high as that of the active area 900. In one embodiment, the top surface of the STI structure 400 is higher than that of the active area 900, as shown in FIG. 7. The hard mask layer 1000 is removed by an etching process selective to the underlying oxide.

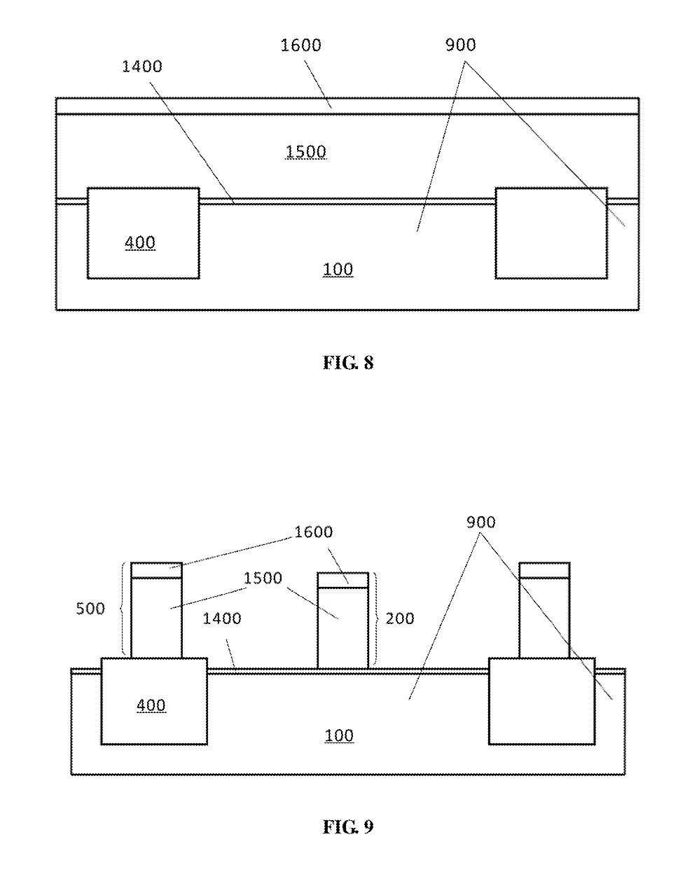

Step c: a gate stack 200 is formed on the active area 900, and a dummy gate 500 is formed on the STI structure 400. Specifically, as shown in FIG. 8, first, the oxide liner 800 is partly etched to form a thinner oxide layer as a gate dielectric layer 1400. Optionally, the gate dielectric layer 1400 may also be a high-k dielectric layer. In this case, the oxide liner 800 is fully removed in the etching process, and then a high-k dielectric layer is formed as the gate dielectric layer 1400, which has a thickness ranging from 1 nm to 3 nm. The high-k dielectric layer is made of hafnium-based materials such as one or more materials selected from HfO₂, HfSiO, HfSiON, HfTaO, HfTiO. and HrZrO, and/or other suitable materials. Then, a gate conductor layer is formed on the gate dielectric layer 1400 (not shown in FIG. 8). The gate conductor layer may be a metal layer formed by a physical vapor deposition (PVD, comprising: evaporation, sputtering, and electron beam, and so on) process, CVD (chemical vapor deposition) process, electroplating, or other suitable processes. Next, a polysilicon layer 1500 which has a thickness ranging from 50 nm to 150 nm is deposited. Then, a nitride layer 1600 which has a thickness ranging from 20 nm to 50 nm is deposited.

Next, the gate stack 200 and the dummy gate 500 are formed by using traditional processes. Specifically, the nitride layer 1600 and the polysilicon layer 1500 are etched sequentially by using a photoresist, which is patterned with a predetermined mask-plate, and using the gate dielectric layer 1400 as a stopper surface. Then, the photoresist is removed, such that the gate stack 200 and the dummy gate 500 are formed, as shown in FIG. 9, wherein the gate stack 200 is on the active area 900, and the dummy gate is on the STI structure 400.

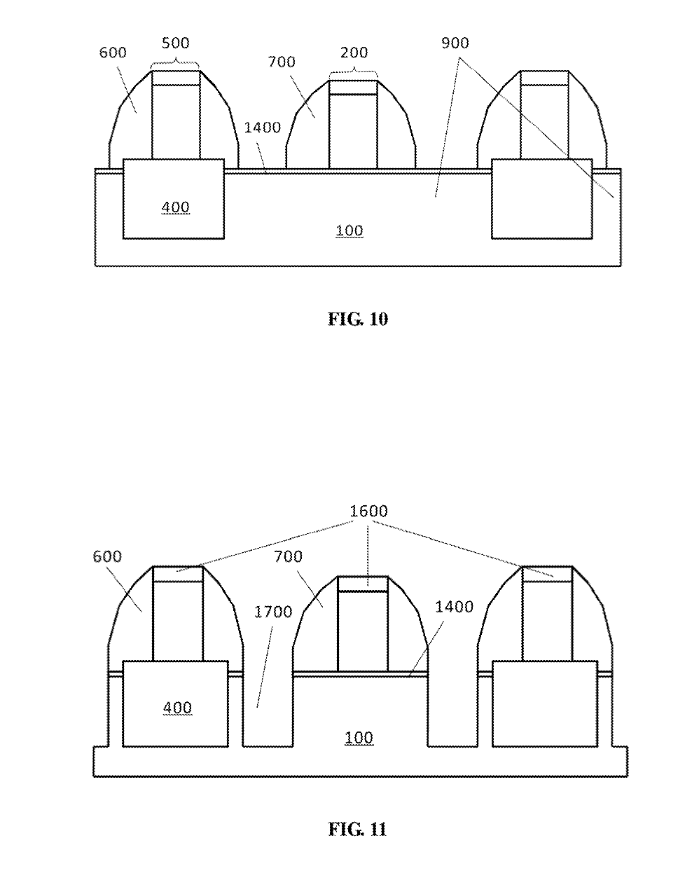

Step d: a first spacer 600 is formed on the sidewalls of the dummy gate 500, wherein a part of the first spacer 600 lands on the active area 900 of the semiconductor substrate. Optionally, according to FIG. 10, a second spacer 700 is formed on the sidewalls of the gate stack 200 meanwhile. The first spacer and the second spacer may be made of the same material, for example, one or more materials selected from silicon nitride, silicon oxide, SiON, SIC, fluoride-doped silica glass, and/or other suitable materials. The spacers may be formed by firstly depositing dielectric material and then performing RIE, and by using the gate dielectric layer 1400 as the stopper surface. It should be noted that the first spacer 600 is partly on the STI structure 400, and partly on the active area 900 of the semiconductor substrate, which is shown in FIG. 10 and has the following advantages. Firstly, the STI structure 400 under the dummy gate 500 is fully covered such that the STI structure 400 is protected from being damaged in the following processes, such as excessive cleaning, etching, and so on. Secondly, a part of the substrate on one side of the STI structure can be reserved while being etching to form the source/drain region and can be used as a seeding layer in an epitaxial growth process, and thus the quality of the source/drain region can be improved.

Optionally, before forming the first spacer and the second spacer, a tilt-angle ion implantation may be performed on the active area 900 of the semiconductor substrate to form halo implanted regions (not shown in the figures) according to requirements, and/or to form source/drain extension regions (not shown in the figures). As for nMOSFETs, the tilt-angle ion implantation, for example, may be performed to form the halo implant region, by using a p-type dopant such as B, BF₂, or a combination of B and BF₂, and can be performed to form the source/drain extension regions, through using an n-type dopant such as As, P, or a combination thereof As and P. As for pMOSFETs, the tilt-angle ion implantation, for example, may be performed to form the halo implant regions by using an n-type dopant such as As, P, or a combination of As and P, and may be performed to form the source/drain extension regions by using a p-type dopant such as or a combination thereof B and BF.

Step e: embedding the source/drain stressors 300 in the semiconductor substrate 100 at opposite sides of the gate stack 200. The top surface of the STI structure 400 is higher than or as high as that of the source/drain stressor 300. Specifically, the gate dielectric layer 1400 and the semiconductor substrate 100 are etched through RIE and by using the first spacer 600 and the second spacer 700 as a mask, in order to form a groove 1700 inside the semiconductor substrate 100 and on both sides of the gate stack 200. A part of the semiconductor substrate is reserved between the groove 1700 and the STI structure 400, according to FIG. 11. It should be noted that, because of the protection from the nitride layer 1600, the first spacer 600, and the second spacer 700, no mask is needed in the etching process in this step.

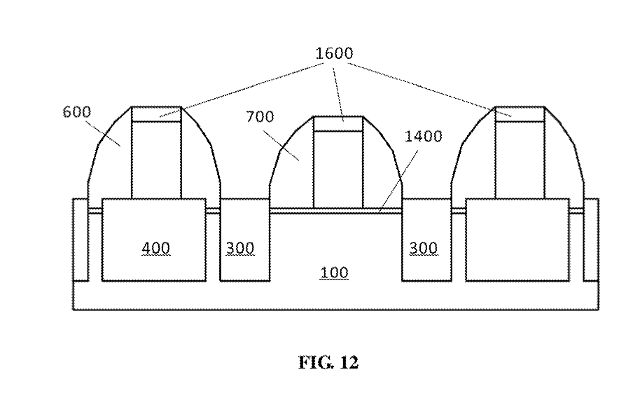

Referring to FIG. 12, the source/drain stressors 300 are formed inside the grooves 1700 by an epitaxial growth process and using the part of the semiconductor substrate reserved as a seeding layer, in order that a stress is generated on both sides of the channel and the carrier mobility of the channel is increased. It should be noted that, as a part of the spacer 600 is formed on the active area 900 of the semiconductor substrate, a part of the semiconductor substrate is reserved between the groove 1700 and the STI structure 400 after the RIE etching process. In other words, the sidewall of the groove 1700 is made of the semiconductor substrate material but not the STI material. Therefore, the source/drain region (the source/drain stressor 300 in the embodiment of the present invention) is formed through the epitaxial growth process by using the part of the semiconductor substrate reserved as a seeding layer, and thus the quality of the source/drain region can be improved. Specifically, for nMOSFETs, the source/drain stressor having a tensile stress may be formed through epitaxially growing Si:C, wherein the percentage of C in the Si:C ranges from 0.2% to 2%, and an in-situ doping with P or As may be performed according to demands. For nMOSFETs, the source/drain stressor having a compressive stress may be formed through epitaxially growing SiGe, wherein the percentage of Ge in the SiGe ranges from 15% to 70%, and an in-situ doping with B maybe performed according to demands.

Optionally, after the Step e, the method further comprises forming a metal silicide layer 1800 on the top of the gate stack 200, the dummy gate 500, and the source/drain stressor 300, as shown in FIG. 2. The metal silicide layer 1800 may be performed through the method known to those skilled in the art. In one embodiment, the metal silicide layer 1800 is made of NiPtSi. Firstly, the hard mask layer 1600 covering the gate stack 200 and the dummy gate 500 may be etched by RIE method until the top of the gate stack 200 and the dummy gate 500 are exposed, and then metals such as Ni or Pt are deposited and an annealing process is performed. The Ni and Pt react with the silicon substrate (polysilicon in the gate stack 200 and the dummy gate 500) or the siliciferous substrate (silicon in the source/drain stressor 300) to form NiPtSi, and the reacted Ni and Pt may be removed by a dry etching process or a wet etching process, and thus the metal silicide NiPtSi is formed.

According to embodiments of the present invention, a STI structure which has a top surface higher than or as high as that of a source/drain stressor is formed, and a dummy gate structure and a spacer are added on the STI structure in a MOSFET device. The structure formed according to the embodiments can effectively prevent the height of the STI structure from being reduced by subsequent processes, such as excessive cleaning, etching, and so on, and thus the channel stress loss can be reduced or avoided, and the performances of the device may be improved. In addition, a part of the spacer is laid on the active area of the semiconductor substrate. Thus, a part of the substrate on one side of the STI structure can be reserved when being etched to forming a groove for the source/drain region. Therefore, a source/drain region can be formed through epitaxial growth by using the reserved part of the substrate as a seeding layer, and thus the quality of the source/drain region can be improved.

Although the present invention has been disclosed as above with reference to preferred embodiments thereof but will not be limited thereto. Those skilled in the art can modify and vary the embodiments without departing from the spirit and scope of the present invention. Accordingly, the scope of the present invention shall be defined in the appended claims.

Every embodiment is described in one-by-one manner in the present invention. The difference between different embodiments is emphasized, and the same or similar content between the embodiments is not repeated. The description serves to explain the principles of the embodiments of the invention and to enable a person skilled in the art to make and use the invention. Modification to these embodiments is obvious to those skilled in the art and general principles defined in the text can be realized in other embodiments without departing from the sprit or scope of the present invention. So, the present invention cannot be limited in these embodiments, but accords with the broadest scope in accordance with the principles disclosed in the text.

What is claimed is:

1. A semiconductor structure, comprising:
a semiconductor substrate;
a gate stack on the semiconductor substrate;
source/drain stressors on opposite sides of the gate stack and embedded in the semiconductor substrate;
a shallow trench isolation structure embedded in the semiconductor substrate, the shallow trench isolation structure having a top surface higher than or as high as a top surface of the source/drain stressor and dividing the semiconductor substrate to form isolated active areas; and
a dummy gate formed on the top surface of the shallow trench isolation structure, wherein a first spacer is formed on sidewalls of the dummy gate, and a part of the first spacer lands on the active area.

2. The semiconductor structure according to claim 1, wherein for pMOSFETs, the source/drain stressors comprises SiGe in which Ge percentage ranges from 15% to 70%; and for nMOSFETs, the source/drain stressors comprises Si:C in which C percentage ranges from 0.2% to 2%.

3. The semiconductor structure according to claim 1, wherein a second spacer is formed on the sidewalls of the gate stack.

4. A method for manufacturing a semiconductor structure, comprising:
a: providing a semiconductor substrate;
b: embedding a shallow trench isolation structure in the semiconductor substrate to form isolated active areas, wherein a top surface of the shallow trench isolation structure is higher than or as high as a top surface of the active area;
c: forming a gate stack on the active area, and forming a dummy gate on the shallow trench isolation structure;
d: forming a first spacer on sidewalls of the dummy gate, wherein a part of the first spacer lands on the active area; and
e: forming source/drain stressors in the semiconductor substrate on opposite sides of the gate stack, wherein the top surface of the shallow trench isolation structure is higher than or as high as a top surface of the source/drain stressors.

5. The method for manufacturing a semiconductor structure according to claim 4, wherein the step b for forming the shallow trench isolation structure comprises:
forming a hard mask layer on the semiconductor substrate;
etching the hard mask layer and the semiconductor substrate to form a trench;
filling the trench to form an insulating layer;
etching back the insulating layer until a top surface of the insulating layer is higher than or as high as the top surface of the active area; and
removing the hard mask layer.

6. The method for manufacturing a semiconductor structure according to claim 4, wherein the step d further comprises: forming a second spacer on the sidewalls of the gate stack.

7. The method for manufacturing a semiconductor structure according to claim 6, further comprising: before forming the first spacer and the second spacer, performing a tilted-angle ion implantation on the active area of the semiconductor substrate to form halo implant regions and/or to form source/drain extension regions.

8. The method for manufacturing a semiconductor structure according to claim 6, wherein the step e of forming source/drain stressors comprises:
etching the semiconductor substrate by using the first spacer and the second spacer as a mask to form a groove in the semiconductor substrate and on both sides of the gate stack, wherein a part of the semiconductor substrate between the groove and the shallow trench isolation structure is reserved; and
forming the source/drain stressor in the groove by an epitaxial growth process with the reserved part of the semiconductor substrate as a seeding layer.

9. The method for manufacturing a semiconductor structure according to claim 8, wherein forming the source/drain stressor by the epitaxial growth process comprises:
for pMOSFETs, epitaxially growing SiGe in which Ge percentage ranges from 15% to 70% in the groove; and
for nMOSFETs, epitaxially growing Si:C in which C percentage ranges from 0.2% to 2% in the groove.
